(19) United States
(12) Patent Application Publication
(10) Pub. No.: US 2017/0107342 A1
(43) Pub. Date: Apr. 20, 2017

(54) PROTEIN FILM PRODUCTION METHOD

(71) Applicants: NATIONAL UNIVERSITY CORPORATION NAGOYA UNIVERSITY, Nagoya-shi (JP); NATIONAL INSTITUTE OF ADVANCED INDUSTRIAL SCIENCE AND TECHNOLOGY, Tokyo (JP); KYORIN UNIVERSITY, Tokyo (JP)

(72) Inventors: Masaru HORI, Nagoya-shi (JP); Kenji ISHIKAWA, Nagoya-shi (JP); Yuzuru IKEHARA, Tsukuba-shi (JP); Sanae IKEHARA, Tsukuba-shi (JP); Hajime SAKAKITA, Tsukuba-shi (JP); Yoshihiro AKIMOTO, Mitaka-shi (JP)

(73) Assignees: NATIONAL UNIVERSITY CORPORATION NAGOYA UNIVERSITY, Nagoya-shi (JP); NATIONAL INSTITUTE OF ADVANCED INDUSTRIAL SCIENCE AND TECHNOLOGY, Tokyo (JP); KYORIN UNIVERSITY, Tokyo (JP)

(21) Appl. No.: 15/352,436

(22) Filed: Nov. 15, 2016

Related U.S. Application Data
(63) Continuation of application No. PCT/JP2015/002450, filed on May 14, 2015.

(30) Foreign Application Priority Data
May 16, 2014 (JP) 2014-102455

(51) Int. Cl. C08J 5/18; B29C 35/08; H01J 37/32; B29C 67/24

(52) U.S. Cl. CPC C08J 5/18; B29C 67/24; B29C 35/0866; H01J 37/32816; H01J 37/32449; C08J 2389/00; B29K 2089/00; H01J 2237/33

(57) ABSTRACT

This technique provides a protein film production method which can form a protein film, with denaturation of protein being prevented. The protein film production method includes mixing a protein with an aqueous solvent, to thereby form an aqueous protein solution PAS1, and treating the aqueous protein solution PAS1 with plasma generated by a plasma generator 100. The plasma generated by the plasma generator 100 has a plasma density of 1×10¹³ cm⁻³ to 1×10¹⁵ cm⁻³.

### BACKGROUND OF THE INVENTION

Technical Field

The technical field of the specification relates to a protein film production method. More particularly, the technical field relates to a method for producing a protein film from an aqueous solution of protein.

Background Art

Films formed by synthesizing a protein are used as industrial materials and food materials. For example, a raw material of bean-curd skin, Yuba. Patent Document 1 discloses a technique of producing a Yuba-like food product by applying overheated steam to a film-form soy bean protein-containing material, e.g., soymilk.

Examples of the protein film industrial material include films and fibers. Patent Document 2 discloses a technique of producing reduced keratin, the technique including reducing a keratin-containing substance with a reducing agent in an aqueous medium containing a protein-denaturing agent, removing insoluble matter, and subjecting the liquid to salting out.

Patent Document 1: Japanese Patent Application Laid-Open (kokai) No. 2008-104372

Patent Document 2: Japanese Patent Application Laid-Open (kokai) No. 1994-100600

Meanwhile, when a synthetic protein film is employed as a medical material, denaturation of the relevant protein is preferably prevented. However, in the technique disclosed in Patent Document 1, the protein is denatured in the heat treatment. Also, in the technique disclosed in Patent Document 2, the protein is denatured in the chemical treatment.

### SUMMARY OF THE INVENTION

The technique of the specification has been conceived in order to solve the problems involved in the aforementioned conventional techniques. Thus, an object is to provide a protein film production method which can form a protein film, with denaturation of protein being prevented.

In a first aspect of the protein film production method, the method includes an aqueous protein solution production. step of mixing a protein with an aqueous solvent, me thereby form an aqueous protein solution, and a plasma application step of applying plasma generated by a plasma generator to the aqueous protein solution.

In the protein film production method, the protein solution is treated with non-thermal atmospheric-pressure plasma substantially at room temperature. The electric discharge gas has room temperature. The plasma supplied. through the outlet of the plasma generator intermingles and reacts with air. As a result, the temperature of the plasma at the liquid surface of the aqueous protein solution is almost the same as room temperature. Thus, heat-induced protein denaturation is prevented.

In a second aspect of the protein film production method, the method employs the following plasma conditions. Specifically, the plasma density of the plasma generated by the plasma generator is 1×10¹³ cm⁻³ to 1×10¹⁵ cm⁻³. Since the plasma density is high, protein film can be suitably formed.

In a third aspect of the protein film production method, the method employs the below-described plasma generator. The plasma generator has a tubular first electrode, a second electrode, and an insulating tube. A first end of the first electrode is disposed inside the insulating tube. The second electrode is disposed outside the insulating tube. The first end of the first electrode includes a protruded part. The protruded part is provided with a microhollow.

In a fourth aspect of the protein film production method, the plasma generator has a third electrode disposed outside the insulating tube. The third electrode is disposed at a position from the insulating tube more distal to the second electrode.

In a fifth aspect of the protein film production method, each of the second electrode and the third electrode of the plasma generator is a tubular electrode. The second electrode is disposed inside the tube of the third electrode.

In a sixth aspect c the protein film production method, the first electrode of the plasma generator has, at a second end side, a gas-supplying part for supplying an electric discharge gas. The gas-supplying part communicates with the inside of the tubular first electrode.

The specification provides a protein film production method which can form a protein film, with denaturation of protein being prevented.

### BRIEF DESCRIPTION OF THE DRAWINGS

FIG. 1 A schematic configuration of a plasma generator according to an embodiment.

FIG. 2 A perspective view of a first electrode of the plasma generator according to the embodiment.

FIG. 3 A cross-section of the first electrode of the plasma generator according to the embodiment.

FIG. 4 A cross-section showing a variation of an inner electrode of the plasma generator according to the embodiment.

FIG. 5 A sketch for describing the protein film production method according to the embodiment.

FIG. 6 A microscopic photoimage of an aqueous protein solution.

FIG. 7 A misroscopic photoimage of an aqueous protein solution, after being treated with helium gas.

FIG. 8 A microscopic photoimage aqueous protein solution, after being treated with plasma for 3 minutes.

FIG. 9 A microscopic photoimage of an aqueous protein solution, after being treated with plasma for 1 minute.

FIG. 10 A photoimage of an aqueous protein solution having an ovalbumin concentration of 0.5 mg/mL, after being treated with plasma for 30 seconds.

FIG. 11 A photoimage of an aqueous protein solution having an ovalbumin concentration of 1.0 mg/mL, after being treated with plasma for 30 seconds.

FIG. 12 A photoimage of an aqueous protein solution having an ovalbumin concentration of 5.0 mg/mL, after being treated with plasma for 30 seconds.

FIG. 13 A photoimage of a protein film in an aqueous protein solution formed by plasma treatment.

FIG. 14 A photoimage of the protein film removed from the aqueous protein solution.

FIG. 15 An electron microscopic photoimage of the protein. film (×4,000).

FIG. 16 An electron microscopic photoimage of the protein film (×20,000).

FIG. 17 A photoimage of an aqueous protein solution of ovalbumin (egg white albumin), after being treated with plasma.

FIG. 18 A photoimage of an aqueous protein solution of bovine serum albumin (BSA), after being treated with plasma.

### DETAILED DESCRIPTION OF PREFERRED EMBODIMENTS

Hereinafter, specific embodiments of the protein film production method will be described, with reference to drawings. In a protein film production method of the embodiments, a film-form coagulated protein is produced by treating an aqueous solution containing a protein with plasma, The plasma generator employed in the embodiments includes members having arbitrary dimensions. The sizes of the members of the plasma generator are not limited to the below described values.

### 1. Plasma Generator

### 1-1. General Configuration of Plasma Generator

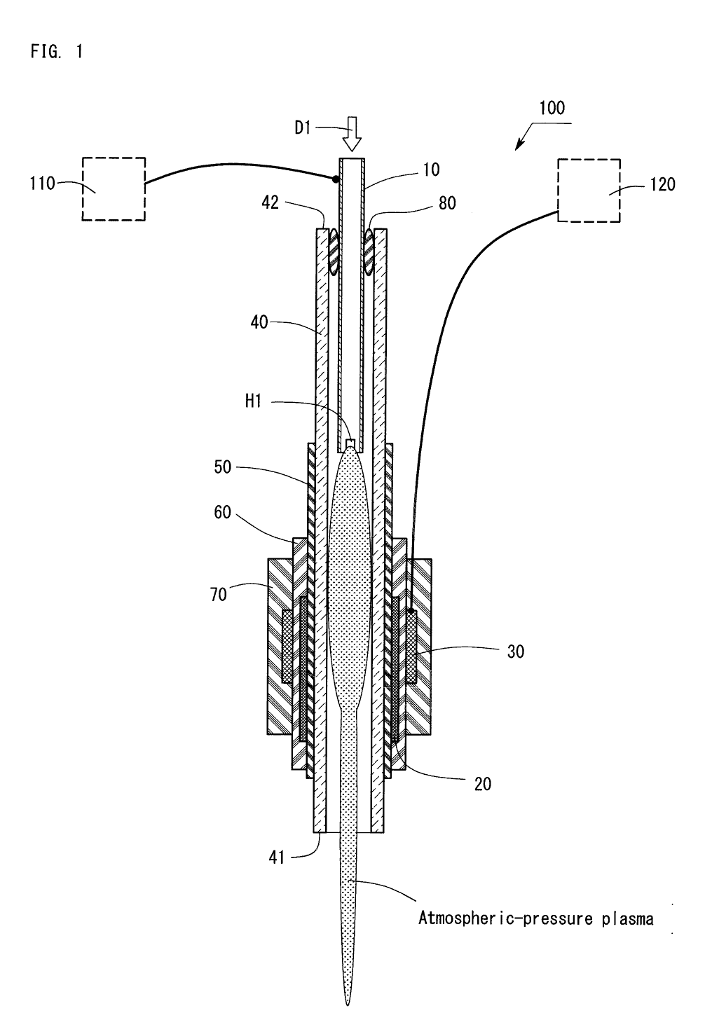

FIG. 1 shows a schematic configuration of a plasma generator 100 of an embodiment. The plasma generator 100 has a first electrode 10, a second electrode 20, a third electrode 30, an insulating tube 40, a first insulating member 50, a second insulating member 60, a third insulating member 70, a sealing member 80, a first electric potential-providing part 110, and a second electric potential-providing part 120.

The first electrode 10 serves as a discharge electrode. The first electrode 10 also serves as a gas-supplying tube for supplying an electric discharge gas. For attaining the functions, the first electrode 10 assumes a tubular electrode having a cylindrical, shape. So long as the shape is tubular, the cross-section of the first electrode 10 may be a polygon or another shape. The first electrode 10 has a distal end provided with a microhollow H1 as mentioned below. The distal end of the first electrode 10 is disposed inside the insulating tube 40. The first electrode 10 has a proximal end which is exposed to the outside of the insulating tube 40. The first electrode 10 is made of a material such as stainless steel (SUS). Needless to say, the material may be other metals or alloys. The outer diameter of the first. electrode 10 is, for example, 1 mm to 5 mm. The pipe thickness of the first electrode 10 is, for example, 0.1 mm to 0.5 mm. However, these values are merely examples, and measurements other than the above values may be employed.

The second electrode 20 is a tubular electrode. So long as the shape is tubular, the cross-section of the second electrode 20 may be a polygon or another shape. The second electrode 20 is provided so as to cover the first insulating member 50. Thus, the insulating tube 40 and the first insulating member 50 are disposed in the tubular second electrode 20. In other words, the second electrode 20 is disposed outside the insulating tube 40. However, the first electrode 10 is not located in the tubular second electrode 20. In the case where the tube of the second electrode 20 is extended along the center axis of the tube, the first electrode 10 is located in the extended tube. Also, the second electrode 20 is interposed between the first insulating member 50 and the second insulating member 60. Thus, the second electrode 20 is thoroughly surrounded by an insulating body. The second electrode 20 is made of a material such as aluminum. Needless to say, the material may be other metals (including alloys). The pipe thickness of the second electrode 20 is about 1 mm.

The third electrode 30 is a tubular electrode. So long as the shape is tubular, the cross-section of the third electrode 30 may be a polygon or another shape. The third electrode 30 is provided so as to cover the second insulating member 60. Thus, the insulating tube 40, the first insulating member 50, the second electrode 20, and the second insulating member 60 are disposed from the center axis of the tubular third electrode 30. In other words, the third electrode 30 is disposed outside the insulating tube 40. In addition, the third electrode 30 is disposed at a position from the insulating tube 40 more distal to the second electrode 20. Also, the third electrode 30 is interposed between the second insulating member 60 and the third insulating member 70. Thus, the third electrode 30 is thoroughly surrounded by an insulating body. The third electrode 30 is made of a material such as aluminum. Needless to say, the material may be other metals (including alloys). The pipe thickness of the third electrode 30 is about 1 mm.

The insulating tube 40 serves as a casing of the plasma generator 100. The insulating tube 40 is disposed between the first electrode 10 and the second electrode 20. The first electrode 10 is disposed inside the insulating tube 40, and the second electrode 20 and the third electrode 30 are disposed outside the insulating tube 40. The insulating tube 40 may be made of a material such as alumina, zirconia, magnesia, mullite, or glass, or other materials. The inner diameter of the insulating tube 40 is about 10 mm to about 30 mm. The pipe thickness of the insulating tube 40 is about 0.2 mm to about 2 mm. The length of the insulating tube 40 is about 10 cm to about 15 cm.

The insulating tube 40 is opened at the distal end, serving as an opening 41. As shown in FIG. 1, the opening 41 serves as a plasma radiation outlet through which plasma is supplied. At the proximal end 42 of the insulating tube 40, opposite the opening 41, the first electrode 10 protrudes. At the end 42, the space between the insulating tube 40 and the first electrode 10 is filled with the sealing member 80. At the side of the first electrode 10 opposite the microhollow H1 side, a gas-supplying member (not illustrated) is provided. The gas-supplying member communicates with the inside of the tubular first electrode 10 by the mediation a tube or the like. As a result, the plasma generator 100 can supply an electric discharge gas toward the direction represented by an arrow D1 in FIG. 1.

The first insulating member 50 enhances the dielectric strength of the insulating tube 40. The first insulating member 50 is formed so as to cover the outer peripheral surface of the insulating tube 40. The first insulating member 50 may be made of polyimide, Telfon (registered trademark), or the like. Other materials may also be employed. The first insulating member 50 in tape form can be readily attached to the outer peripheral surface of the insulating tube 40.

The second insulating member 60 is disposed between the second electrode 20 and the third electrode 30. The second insulating member 60 may be made of the same material as that of the first insulating member 50.

The third insulating member 70 is disposed outside the third electrode 30. The third insulating member 70 may be made of the same material as that of the first insulating member 50.

As shown in FIG. 1, the length of the third electrode 30 along the axial direction of the insulating tube 40 (vertical direction in FIG. I) is smaller than the length of the second electrode 20 along the axial direction or the insulating tube 40 in the axial direction of the insulating tube 40 (vertical direction in FIG. 1), the top longitudinal end of the third electrode 30 is located at a level lower than that of the top longitudinal end of the second electrode 20, and the bottom longitudinal end of the third electrode 30 is located at a level higher than that of the bottom longitudinal end of the second electrode 20. Thus, the electrode in the closest vicinity of the first electrode 10 is not the third electrode 30, but the second electrode 20.

### 1-2. Electric Potential-Providing Part

The first electric potential-providing part 110 imparts an electric potential to the first electrode 10. Thus, the first electric potential-providing part 110 electrically communicates with the first electrode 10. The first electric potential-providing part 110 can elevate a voltage of 100 V provided by a commercial AC (50 Hz, 60 Hz) power source and apply high voltage. By means of an inverter, a high-frequency component of about 10 kHz to about 100 kHz may be further applied. In this way, a voltage is applied between the first electrode 10 and the second electrode 20, so that the first electric potential-providing part 110 imparts an electric potential to the first electrode 10.

The second electric potential-providing part 120 imparts an electric potential to the third electrode 30. Thus, the second electric potential-providing part 120 electrically communicates with the third electrode 30. The second electric, potential-providing part 120 is, for example, grounded. In this case, a zero potential is applied to the third electrode 30. Alternatively, the second electric potential-providing part 120 may impart, to the third electrode 30, a specific electric potential other than 0 V, or a periodically varying electric potential. In this way, a voltage is applied to the second electrode 20 by the mediation of an insulating member 60, so that the second electric potential-providing part 120 imparts an electric potential to the third electrode 30.

### 1-3. Structures of the Second and Third Electrodes

The second electrode 20 and the third electrode 30 are disposed outside the insulating tube 40 and have a double-electrode structure. The second insulating member 60 is interposed between the second electrode 20 and the third electrode 30. By virtue of the double-electrode structure, a pulsewise impact electric field applied to the insulating tube 40 along the thickness direction, the tube being interposed between the first electrode 10 and the second electrode 20, can be somewhat mitigated. In other words, provision of a local, large electric field between the inside and the outside of the tubular insulating tube 40 can be prevented. As a result, dielectric breakdown or the insulating tube 40 is prevented. Thus, such a downscaled plasma generator 100 serves as a stable plasma source.

### 1-4. Shape of First Electrode

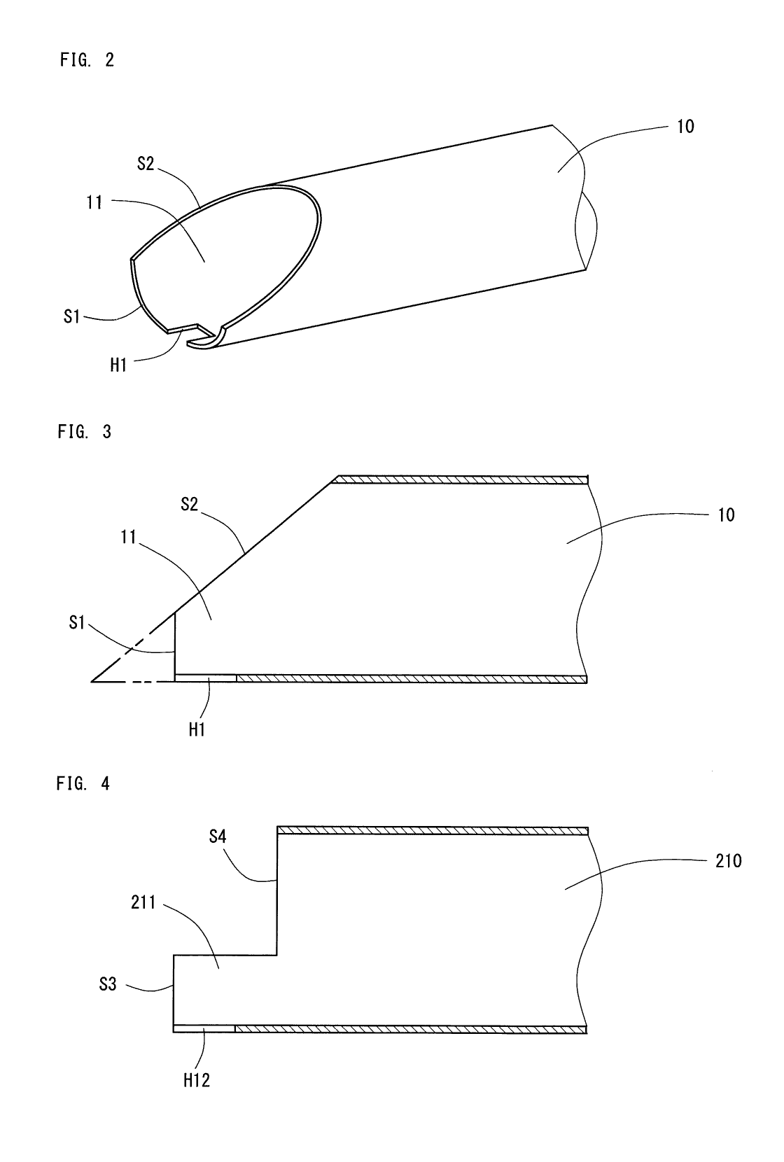

FIG. 2 is a perspective view of an end 11 of the first electrode 10. FIG. 3 is a cross-section of the first electrode 10 including the tube center and the microhollow H1. The end 11 of the first electrode 10 has an end face S1 and a face S2. The end face S1 is a protruded part, which protrudes toward the distal and longitudinal outside of the first electrode 10, as compared with the face S2. That is, the end 11 of the first electrode 10 is not axially symmetric.

The end face S1 is provided with the microhollow H1. The microhollow H1 is a slit-like cut-out. The microhollow H1 has a depth of 0.3 mm to 0.5 mm. The width of the microhollow M1 is 0.1 mm to 0.3 mm. These values are merely examples, and any other measurements may be employed.

By virtue of such a structure, electric discharge readily occurs around the microhollow H1 of the protruded end face S1. As a result, high-density plasma can be generated readily and reliably.

The field intensity of the electric field provided between the first electrode 10 and the second electrode 20 is proportional to the voltage applied thereto and inversely proportional to the interelectrode distance. Therefore, the electric potential provided by the first electric potential-providing part 110 and the distance between the first electrode 10 and the second electrode 20 are important factors.

For producing a small-scale plasma generator 100, the outer diameter of the insulating tube 40 is reduced, and the distance between the first electrode 10 and the second electrode 20 is augmented. That is, the end face S1 of the first electrode 10 can be located at a position relatively distant from the second electrode 20. The distance between the end face S1 of the first electrode 10 and the side face 42 of the second electrode. 20 is preferably about 8 mm to 35 mm.

### 1-5. Variations of Plasma Generator

### 1-5-1. Shape of Inner Electrode

In the embodiment, the first electrode 10 shown in FIGS. 1 to 3 is employed as an inner electrode disposed in the insulating tube 40. However, the shape of the inner electrode is not limited to the above first electrode 10. For example, an inner electrode 210 shown in FIG. 4 may be employed. An end 211 of the inner electrode 210 has an end. face S3 and a face 54. The end face S3 is a protruded part, which protrudes toward the distal and longitudinal outside of the inner electrode 210, as compared with the face S4. That is, the end 211 of the inner electrode 210 is not axially symmetric. The end face 53 is provided with a hollow H12. Thus, the hollow H12 is provided at the part of the inner electrode most protruded toward the longitudinal outside,

### 1-5-2. Number of Microhollow(s)

In the embodiment, the end face S1 of the first electrode 10 is provided with one microhollow H1. However, the end face S1 may be provided with a plurality of microhollows H1.

### 1-5-3. Shape of Outer Electrode

In the embodiment, the second electrode 20 and the third electrode 30 are employed as tubular electrodes. However, these electrodes are not necessarily tubular, so long as the second electrode is disposed between the first electrode 10 and the third electrode 30.

### 1-5-4. Combination

The aforementioned variations may be combined.

### 2. Plasma to be Generated

The plasma generated by the plasma generator 100 is non-thermal atmospheric-pressure plasma. The flow of the electric discharge gas is preferably 0.5 slm to 5 slm. The density of the generated plasma is about 1×10¹³ cm³ to about 1×10¹⁵ cm⁻³. In the below-described experiments, a rare gas is used as an electric discharge gas. The plasma discharged through the opening 41 intermingles with air. Therefore a variety of radical species and the like originating from oxygen and nitrogen generate.

### 3. Aqueous Protein Solution

In this embodiment, an aqueous protein solution is treated with plasma. Thus, an aqueous protein solution containing a protein will next be described. The aqueous protein solution is an aqueous solution prepared by mixing a protein with ultra-pure water.

As the protein, purified albumin may be used. Examples of such purified albumin include ovalbumin, bovine serum albumin (BSA), and fetuin. One or more species of these are preferably used.

### 4. Protein Film Production Method

Next, the protein film production method will be described. The protein film production. method of the embodiment includes an aqueous protein solution production step of mixing a protein with an aqueous solvent, to thereby form an aqueous protein solution, and a plasma application step of applying plasma generated by a plasma generator to the aqueous protein solution.

### 4-1. Aqueous Protein Solution Production Step (Aqueous Protein Solution Preparation Step)

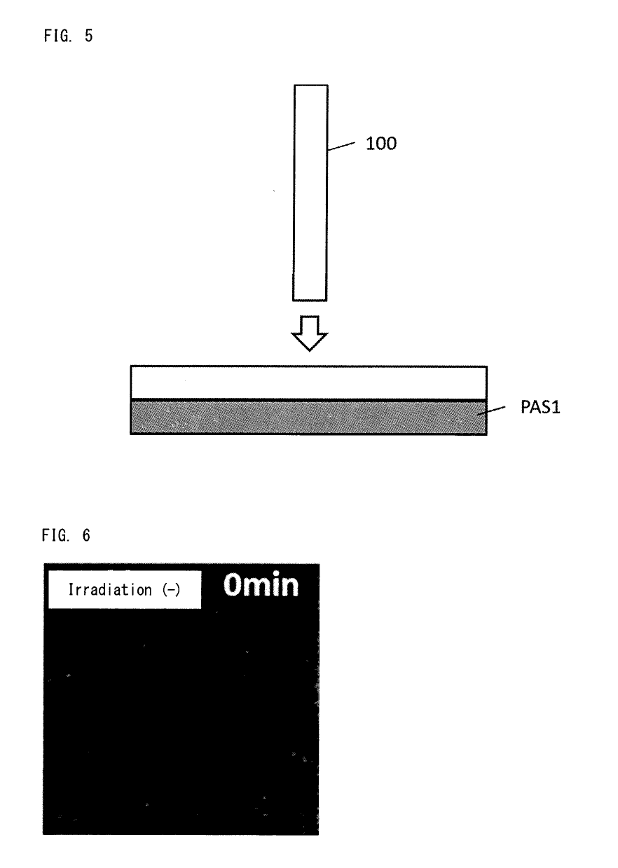

Firstly, an aqueous protein solution is prepared. Specifically, ultra-pure water is added to a container, and a protein is mixed with the ultra-pure water in the container. The protein to be mixed with water is purified in advance. If the protein is unpurified, purification is performed. Through the above procedure, an aqueous protein solution PAST (see FIG. 5) is prepared.

### 4-2. Plasma Application Step

Then, as shown in FIG. 5, the aqueous protein solution PAS1 is treated with plasma by means of the plasma generator 100. The electric discharge gas (plasma gas) is, for example, helium gas. Through plasma treatment, the protein in the aqueous protein solution PAS1 polymerizes, to thereby form a protein film. The thus-formed protein film can be readily removed.

### 5. Produced Protein Film

As described above, the plasma density is about 1×10¹³ cm³ to about 1×10¹⁵ cm⁻³. Through plasma treatment of the solution, for some tens of seconds to some tens of minutes, protein coagulates. Meanwhile, the diameter of the opening 41 of the plasma generator 100 is some millimeters. The flow rate of electric discharge gas is about 0.5 slm to about 5 slm. Therefore, the number of ions and radicals applied to the aqueous protein solution is considerably smaller than the Avogadro constant. Thus, as compared with the protein which is denatured with a denaturing agent or a reducing agent, the protein film of this embodiment is conceived to undergo substantially no denaturation.

### 6. Variations

### 6-1. Raw Materials of Aqueous Protein Solution

In this embodiment, an aqueous protein solution containing a protein (e.g., albumin) is produced. However, other proteins (e.g., globulin, glutelin, and prolamin) may also be used.

### 6-2. Purification of Protein

In this embodiment, the aqueous protein solution is produced from a purified protein. However, the non-purified white of an egg may also be used. Thus, as the protein, ovalbumin, bovine serum albumin (BSA), fetuin, or the non purified white of an egg may be used

### 7. Summary of the Embodiment

The protein film production method of the embodiment includes an aqueous protein solution production step of producing an aqueous protein solution, to thereby form an aqueous protein solution, and a plasma application step of applying plasma to the aqueous protein solution. Through. high density plasma treatment of the protein solution, protein, film can be suitably formed.

Notably, the aforementioned embodiments are given merely as examples. Needless to say, those skilled in the art can conduct various improvements and modifications, so long as the gist of the technique is not impaired. For example, other rare gases such as Ne, Ar, Kr, Xe, and Rn may be used as an electric discharge gas for generating plasma. Also, a small amount of oxygen, nitrogen, and other gases may be present in the electric discharge gas.

### EXAMPLES

### 1. Plasma Generator

The plasma generator employed in the experiment had the following dimensions. The longitudinal (i.e., along the direction of tubular center axis) distance between. the opening 41 and the distal (opening 41 side) end of the second electrode 20 was 7 mm. The longitudinal length of the second electrode 20 was 20 mm. The longitudinal distance between the first electrode 10 and the second electrode 20 was 10 mm. The diameter of the opening 41 was 1 mm.

### 2. Plasma Conditions

The electric discharge gas employed in the experiment was He gas. The flow rate of the discharge gas was 2 slm. As a result, a plasma flow having a diameter of about 1 mm and a length of about 4 cm was observed.

### 3. Aqueous Protein Solution

Milli-Q (registered trademark) was used as ultra-pure water. Three aqueous protein solutions were prepared from the following three proteins: ovalbumin (ovarian albumin: OVA), ovalbumin (egg white: EW), and bovine serum albumin (BSA). Notably, ovalbumin (OVA) and ovalbumin (EW) differ in degree of purification. These three aqueous solutions are the same, except for the purification degree. The protein concentration was tuned in accordance with the type of experiment. The volume of the aqueous protein solution. treated with plasma was 0.3 mL.

### 4. Results of Experiments

### 4-1. Treatment Time

The relationship between plasma treatment time and extent of, protein film formation was experimentally investigated. An aqueous protein solution having an ovalbumin (OVA) concentration of 5.0 mg/mL was used. During plasma treatment, the plasma generator 100 was not shaken.

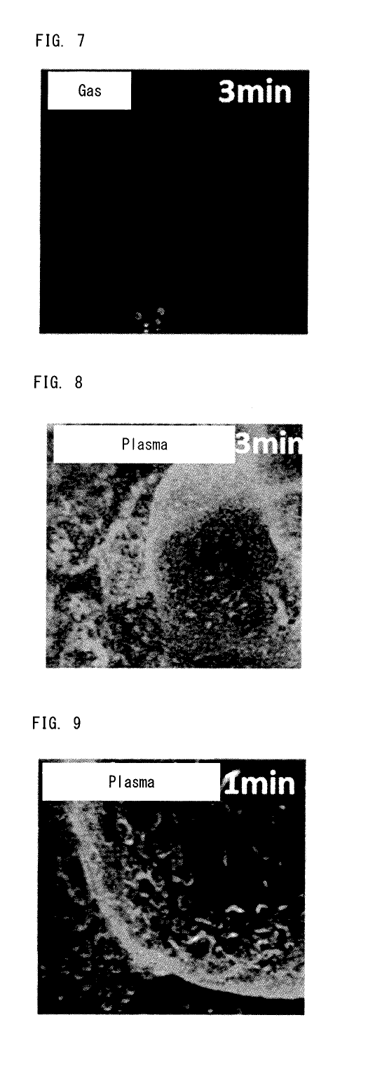

FIG. 6 is a microscopic photoimage of an aqueous protein solution before plasma treatment. FIG. 7 is a microscopic photoimage of an aqueous protein solution, after helium gas treatment in a non-plasma state. FIG. 8 is a microscopic photoimage of an aqueous protein solution, after plasma treatment for 3 minutes. FIG. 9 is a microscopic photoimage of an aqueous protein solution, after plasma treatment for 1 minute. As shown in FIGS. 8 and 9, a film-form coagulated protein was found to be formed in an aqueous protein solution after plasma treatment.

### 4-2. Protein Concentration

Next, the relationship between protein concentration of each aqueous protein solution and the extent of protein film formation was experimentally investigated. Three aqueous protein solutions having ovalbumin (OVA) concentrations of 0.5 mg/mL, 1.0 mg/mL, and 5.0 mg/mL, were used. The plasma treatment time was adjusted to 30 seconds. During plasma treatment, the plasma generator 100 was shaken.

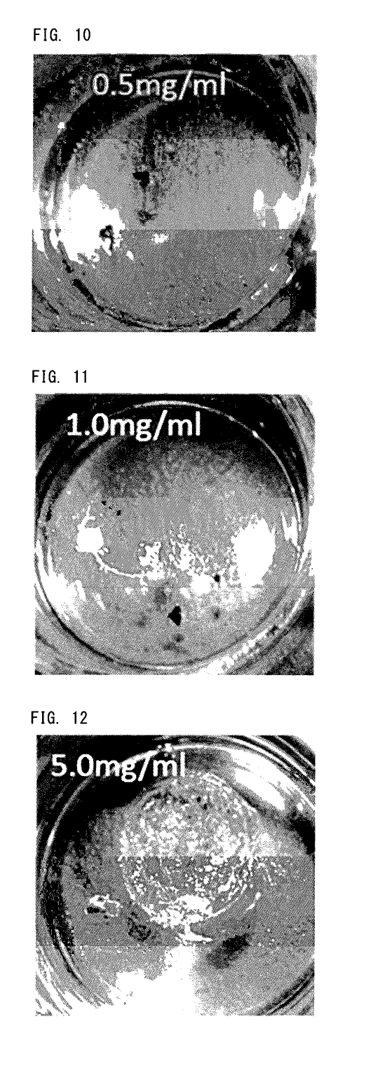

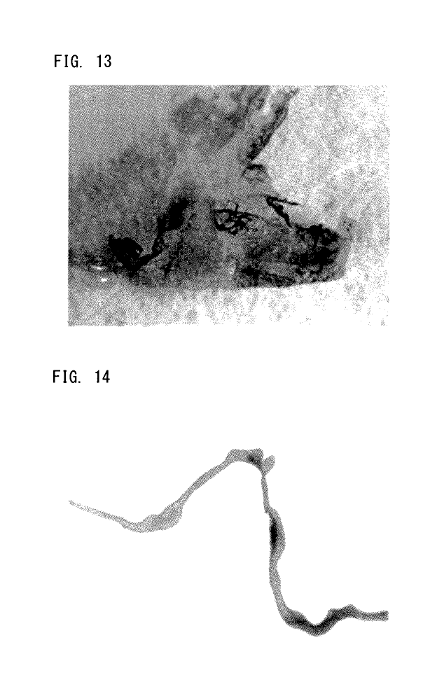

FIGS. 10 is a photoimage of an aqueous protein solution. having an ovalbumin (OVA) concentration of 0.5 mg/mL, after treatment with plasma. FIG. 11 is a photoimage of an aqueous protein solution having an ovalbumin (OVA) concentration of 1.0 mg/mL, after treatment with plasma. FIG. 12 is a photoimage of an aqueous protein solution having an ovalbumin (OVA) concentration of 5.0 mg/mL, after treatment with plasma.

In FIG. 10, formation of a film-form coagulated protein was not observed. In contrast, formation of a film-form coagulated protein was observed in FIG. 11. In FIG. 12, relatively large film-form protein coagulates were formed. Thus, when the ovalbumin (MW concentration of an aqueous protein solution was 1.0 mg/mL or higher, film-form protein coagulates were formed.

### 4-3. Microscopic Observation

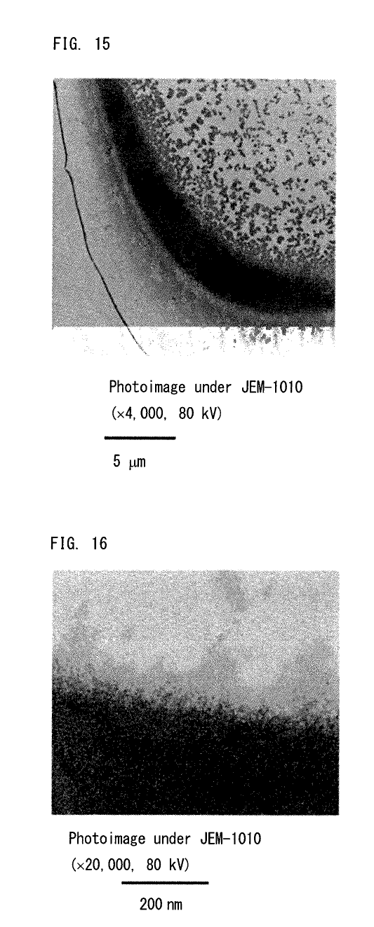

FIG. 13 is a photoimage of a protein film in an aqueous protein solution formed by plasma treatment. FIG. 14 is a photoimage of the protein film, removed from the aqueous protein solution. FIG. 15 is an electron microscopic magnified photoimage of the protein film, with the magnification of ×4,000. FIG. 16 is an electron microscopic magnified photoimage of the protein film, with the magnification of ×20,000.

As shown in FIGS. 15 and 16, the formed protein aggregates were found to have a certain spacing, indicating that the protein underwent no substantial denaturation. The formed protein film is virtually transparent.

### 4-4. Comparison in Terms of Albumin Species

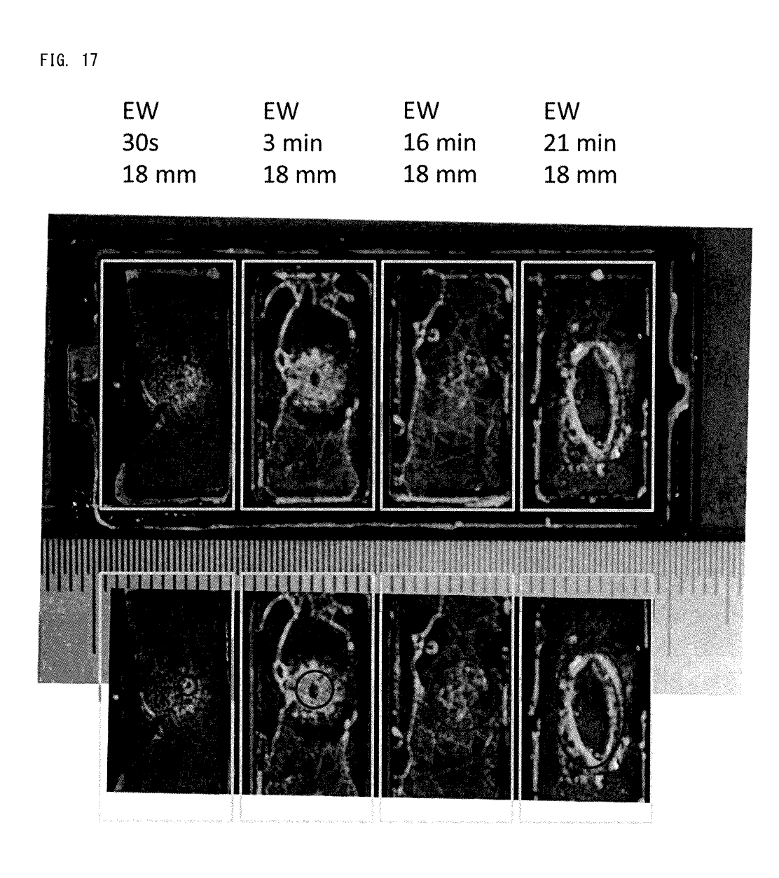

FIG. 17 is a photoimage of an aqueous protein solution containing ovalbumin (EW: egg white albumin), after being treated with plasma. FIG. 17 shows two columns of photographs (i.e., those of upper and lower columns). The photographs of the upper and lower columns are the same, but the photographs of the lower column are marked with a circle or an oval, indicating the presence of protein film. Between the upper and lower columns disposed is a ruler, showing the dimensions of an experimental container (chamber slide) and protein films.

The ovalbumin (EW) concentration was 20 mg/mL. The plasma treatment distance was 18 mm. The photographs of FIG. 17 correspond to plasma treatment times of 30 seconds, 3 minutes, 16 minutes, and 21 minutes, respectively, left to right. As is clear from FIG. 17, the longer the plasma treatment time, the larger the formed protein film.

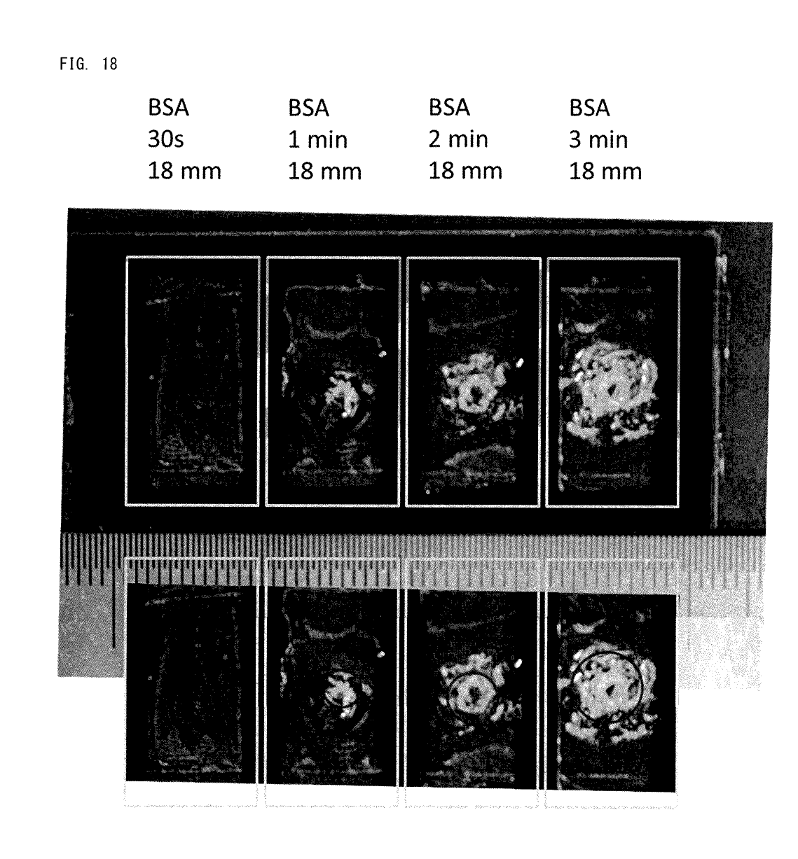

FIG. 18 is a photoimage of an aqueous protein solution containing bovine serum albumin (BSA), after being treated with plasma. Similar to FIG. 17, FIG. 18 shows two columns of photographs (i.e., those of upper and lower columns).

The bovine serum albumin (BSA) concentration was 20 mg/mL. The plasma treatment distance was 18 mm. The photographs of FIG. 18 correspond to plasma treatment times of 30 seconds, 1 minute, 2 minutes, and 3 minutes, respectively, left to right. As is clear from FIG. 18, the longer the plasma treatment time, the larger the formed protein film. Also, even when the plasma treatment time was about 30 seconds, a very small-scale protein film was formed.

### 4-5. Plasma Treatment Distance

Next, protein films were formed under variation of plasma treatment distance. The plasma treatment distance refers to the distance between the application opening of the plasma generator and the liquid surface of the aqueous protein solution. The employed plasma treatment distances were 13 mm, 18 mm and 23 mm. The ovalbumin concentration was 20 mg/mL. When the plasma treatment distance was 13 mm, the largest protein film was formed, whereas when the plasma treatment distance was 23 mm, the smallest protein film was formed. Thus, the shorter the plasma treatment distance, the larger the formed protein film The greater the distance from the application opening of the plasma generator, the lower the plasma density and radical density. In other words, the shorter the plasma treatment distance the greater the amounts of ions and radicals applied to the aqueous protein solution. Thus, the greater the amounts of ions and active species applied to the aqueous protein solution, the larger the formed protein film.

As described above, protein films were obtained by plasma treatment of any of the three aqueous protein solutions.

### 4-6. Bonding State

The thus-obtained protein films were subjected to western blotting. As a result, virtually no peptide bond or sugar linkage was identified. Therefore, no protein denaturation was thought to occur.

### 5. Industrial Applicability

The protein film produced through the protein film production method may be used as, for example, a sticking plaster or applied to producing albumin preparations. Needless to say, the protein film may also be used as an industrial material.

What is claimed is:

1. A protein film production method, comprising:
mixing a protein with an aqueous solvent, to thereby form an aqueous protein solution, and treating the aqueous protein solution with plasma generated by a plasma generator.

2. A protein film production method according to claim 1, wherein the plasma generated by the plasma generator has a plasma density of 1×10¹³ cm⁻³ to 1×10¹⁵ cm⁻³.

3. A protein film production method according to claim 1, wherein the plasma generator comprises:
a tubular first electrode,
a second electrode, and
an insulating tube, wherein the first electrode comprises a first end disposed inside the insulating tube;
the second electrode is disposed outside the insulating tube;
The first end of the first electrode comprises a protruded part; and
the protruded part comprises a microhollow.

4. A protein film production method according to claim 3, wherein:
the plasma generator comprises a third electrode disposed outside the insulating tube, and
the third electrode is disposed at a position from the insulating tube more distal to the second electrode,

5. A protein film production method according to claim 4, wherein:
each of the second electrode and the third electrode of the plasma generator is a tubular electrode, and
the second electrode is disposed inside the tube of the third electrode.

6. A protein film production method according to claim 3, wherein, in the plasma generator,
the first electrode comprises, at a second end side, a gas-supplying part for supplying a electric discharge gas, and
the gas-supplying part communicates with the inside of the tubular first electrode.

7. A protein film production method, comprising:
preparing an aqueous protein solution which is a mixture of a solvent, and a protein, and
treating the aqueous protein solution with plasma generated by a plasma generator, to thereby form a film-form coagulated protein.

8. A protein film production method according to claim 7, wherein the protein comprises at least one of albumin, globulin, glutelin, prolamin, fetuin, and ovalbumin.

9. A protein film production. method according to claim 7, wherein the protein comprises a serum protein.

10. A protein film production method according to claim 7, wherein the plasma generator comprises a first electrode and a second electrode, a voltage is applied between the first electrode and the second electrode to generate plasma.

11. A protein film production method according to claim 7, wherein, in the plasma treatment, plasma temperature at the liquid surface of the aqueous protein solution is substantially equal to room temperature.

12. A protein film production method according to claim 7, wherein, in the plasma treatment, treating the aqueous protein solution with plasma at the selected plasma treatment distance.
